(19) United States
(12) Patent Application Publication
(10) Pub. No.: US 2018/0053688 A1
(43) Pub. Date: Feb. 22, 2018

(54) METHOD OF METAL FILLING RECESSED FEATURES IN A SUBSTRATE

(71) Applicant: Tokyo Electron Limited, Tokyo (JP)

(72) Inventors: Kai-Hung Yu, Watervliet, NY (US); Kandabara N. Tapily, Mechanicville, NY (US); Gerrit J. Leusink, Rexford, NY (US)

(21) Appl. No.: 15/678,017

(22) Filed: Aug. 15, 2017

Related U.S. Application Data
(60) Provisional application No. 62/375,854, filed on Aug. 16, 2016.

(51) Int. Cl. H01L 21/768; H01L 21/285; H01L 23/532; H01L 23/535; C23C 16/06; C23C 16/455

(52) U.S. Cl. CPC H01L 21/76882; H01L 21/28562; H01L 21/76876; H01L 21/76879; C23C 16/45525; H01L 21/76895; H01L 23/53242; H01L 23/535; C23C 16/06; H01L 21/76883

(57) ABSTRACT

A method of void-less metal filling of recessed features in a substrate is provided. The method includes providing a substrate containing recessed features therein, and filling the recessed features with a metal, where the metal is deposited in the recessed features by gas phase deposition at substrate temperature and a gas pressure that promotes bottom-up void-less filling. According to one embodiment, the metal is selected from the group consisting of Ru, Rh, Os, Pd, Ir, Pt, Ni, Co, W, and a combination thereof.

### CROSS-REFERENCE TO RELATED APPLICATIONS

This application is related to and claims priority to U.S. Provisional Patent Application Ser. No. 62/375,854 filed on Aug. 16, 2016, the entire contents of which are herein incorporated by reference.

### FIELD OF THE INVENTION

The present invention relates to methods for void-less metal filling of recessed features for microelectronic devices.

### BACKGROUND OF THE INVENTION

An integrated circuit contains various semiconductor devices and a plurality of conducting metal paths that provide electrical power to the semiconductor devices and allow these semiconductor devices to share and exchange information. Within the integrated circuit, metal layers are stacked on top of one another using intermetal and interlayer dielectric layers that insulate the metal layers from each other.

Normally, each metal layer must form an electrical contact to at least one additional metal layer. Such electrical contact is achieved by etching a feature (i.e., a via) in the interlayer dielectric that separates the metal layers, and filling the resulting via with a metal to create an interconnect. Metal layers typically occupy etched pathways in the interlayer dielectric. A via normally refers to any feature such as a hole, line or other similar feature formed within a dielectric layer that provides an electrical connection through the dielectric layer to a conductive layer underlying the dielectric layer. Similarly, metal layers connecting two or more vias are normally referred to as trenches.

The use of copper (Cu) metal in multilayer metallization schemes for manufacturing integrated circuits creates problems due to high mobility of Cu atoms in dielectrics, such as SiO₂, and Cu atoms may create electrical defects in silicon (Si). Thus, Cu metal layers, Cu filled trenches, and Cu filled vias are normally encapsulated with a barrier material to prevent Cu atoms from diffusing into the dielectrics and Si. Barrier layers are normally deposited on trench and via sidewalls and bottoms prior to Cu seed deposition, and may include materials that are preferably non-reactive and immiscible in Cu, provide good adhesion to the dielectrics, and can offer low electrical resistivity.

An increase in device performance is normally accompanied by a decrease in device area or an increase in device density. An increase in device density requires a decrease in via dimensions used to form interconnects, including a larger aspect ratio (i.e., depth to width ratio). As via dimensions decrease and aspect ratios increase, it becomes increasingly more challenging to form diffusion barrier layers with adequate thickness on the sidewalls of the vias, while also providing enough volume for the metal layer in the via. In addition, as via and trench dimensions decrease and the thicknesses of the layers in the vias and trenches decrease, the material properties of the layers and the layer interfaces become increasingly more important. In particular, the processes forming those layers need to be carefully integrated into a manufacturable process sequence where good control is maintained for all the steps of the process sequence.

Void-less metal filling of recessed features for microelectronic devices has become increasingly more difficult as aspect ratios of the recessed features increase and new methods are needed that enable complete filing of the recessed features with low-resistivity metals.

### SUMMARY OF THE INVENTION

A method is provided for void-less metal feature fill in a microelectronic device. According to one embodiment, the metal may be selected from the group consisting of Ru, Rh, Os, Pd, Ir, Pt, Ni, Co, W, and combinations thereof. According to another embodiment, the metal may be a noble metal that is selected from the group consisting of Ru, Rh, Pd, Os, Ir, Pt, and combinations thereof.

According to an embodiment of the invention, method is provided for metal filling recessed features in a substrate. The method includes providing a substrate containing recessed features therein, and filling the recessed features with a metal, where the metal is deposited in the recessed features by gas phase deposition at substrate temperature and a gas pressure that promotes bottom-up void-less filling. The method can further include, prior to the filling, forming a nucleation layer in the recessed features.

According to another embodiment the method includes providing a substrate containing recessed features therein, and filling the recessed features with Ru metal, where the Ru metal is deposited in the recessed features by gas phase deposition at substrate temperature and a gas pressure that promotes bottom-up void-less filling.

According to yet another embodiment, the method includes providing a substrate containing recessed features therein, and filling the recessed features with Ru metal, where the Ru metal is deposited in the recessed features by chemical vapor deposition (CVD) at substrate temperature between about 130° C. and about 160° C. using Ru₃(CO)₁₂ and CO carrier gas and a gas pressure between about 0.05 mTorr and about 5 mTorr.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A and 1B shows cross-sectional scanning electron microscopy (SEM) images of Ru metal deposition in fine recessed features in a substrate;

FIGS. 2A and 2B shows cross-sectional SEM images of Ru metal filling of fine recessed features in a substrate according to an embodiment of the invention;

FIG. 3 shows cross-sectional SEM images of Ru metal filling of fine recessed features in a substrate according to an embodiment of the invention;

FIG. 4 shows cross-sectional SEM images of Ru metal deposition in wide recessed features in a substrate according to an embodiment of the invention;

FIG. 5 shows cross-sectional SEM images of Ru metal deposition in a wide recessed feature in a substrate according to an embodiment of the invention;

FIGS. 6A-6E show schematic cross-sectional views of bottom-up metal filling mechanism of recessed features according to an embodiment of the invention;

FIGS. 7A-7E show schematic cross-sectional views of bottom-up metal filling mechanism of recessed features according to an embodiment of the invention; and

FIGS. 8A-8C show schematic cross-sectional views of bottom-up metal filling of a recessed feature according to an embodiment of the invention.

### DETAILED DESCRIPTION OF SEVERAL EMBODIMENTS

Methods for void-less metal filling of recessed features in a substrate for microelectronic devices are described in several embodiments. According to one embodiment, the metal may be selected from the group consisting of Ru, Rh, Os, Pd, Ir, Pt, Ni, Co, W, and combinations thereof. According to another embodiment, the metal may be a noble metal that is selected from the group consisting of Ru, Rh, Pd, Os, Ir, Pt, and combinations thereof.

In one example, Ru metal has been identified as a possible interconnect metal since Ru metal has the low electrical resistance that is needed for replacing conventional Cu metal fill in narrow recessed features. It has been shown that Ru metal, with its short effective electron mean free path, is an excellent candidate to meet International Technology Roadmap for Semiconductors (ITRS) resistance requirements as a Cu metal replacement at about 10 nm (5 nm node) minimum feature sizes. Many material and electric properties of Ru metal make it less affected by downward scaling of feature sizes than Cu metal.

In the following examples, Ru metal deposition is used to demonstrate void-less metal filling of recessed features according to embodiments of the invention.

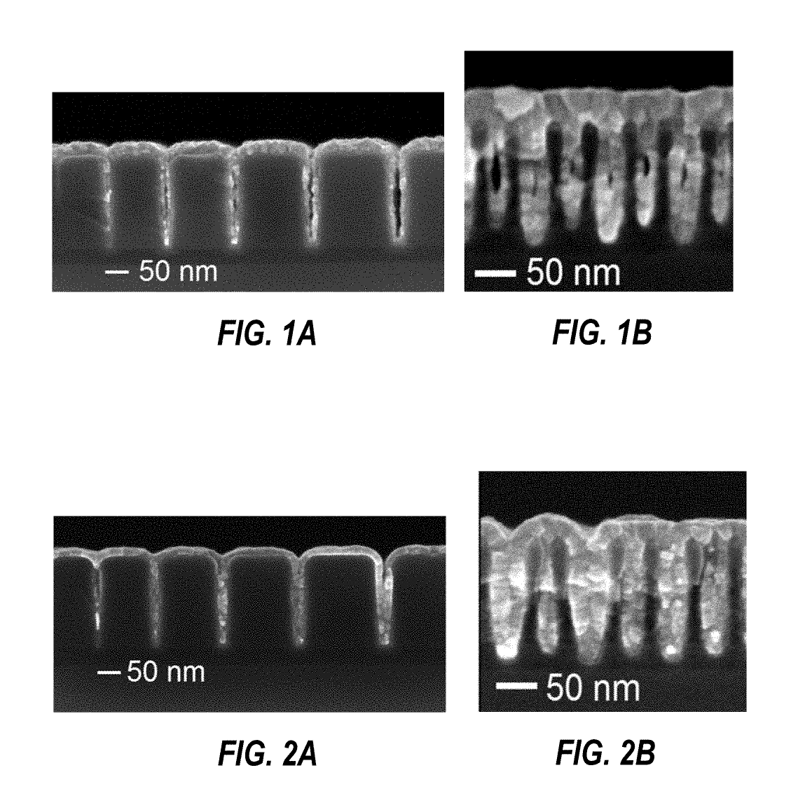

FIGS. 1A and 1B shows cross-sectional SEM images of Ru metal deposition in fine recessed features in a substrate. The recessed features in FIG. 1A had diameters (widths) ranging from about 10 nm (left) to about 40 nm (right) and depths of about 195 nm. The recessed features in FIG. 1B had diameters ranging from about 20 nm to about 35 nm and depths of about 95 nm. Prior to Ru metal deposition, a 1 nm thick TaN nucleation layer was deposited in the recessed features using atomic layer deposition (ALD) with alternating exposures of tert-butylimido-tris-ethylmethylamido-tantalum (TBTEMT, Ta(NCMe₃)(NEtMe)₃) and ammonia (NH₃) at a substrate temperature of about 350° C. A Ru metal layer was deposited at a rate of about 0.5-1.0 nm/min on the TaN nucleation layer by chemical vapor deposition (CVD) at a substrate temperature of about 200° C. using Ru₃(CO)₁₂ and CO carrier gas. The processing conditions further included a gas pressure in the process chamber of about 500 mTorr. The gas pressure was controlled by throttle control using an automated pressure control (APC) system. FIGS. 1A and 1B show that the recessed features were not completely filled with Ru metal and had voids (seams) inside the recessed features. The voids were formed due to pinching of the openings of the recessed features before the recessed features could be completely filled with the Ru metal.

The processing conditions used to deposit the Ru metal shown in FIGS. 1A and 1B may be used to deposit thin conformal Ru metal layers in recessed features, for example for use as a seed layer for plating Cu metal to fill the recessed features. The processing conditions can include a substrate temperature between about 190° C. and about 210° C., and a gas pressure in the process chamber between about 100 mTorr and about 500 mTorr. However, it is clear from FIGS. 1A and 1B that those processing conditions do not result in void-less Ru metal filling of the recessed features and new methods are needed.

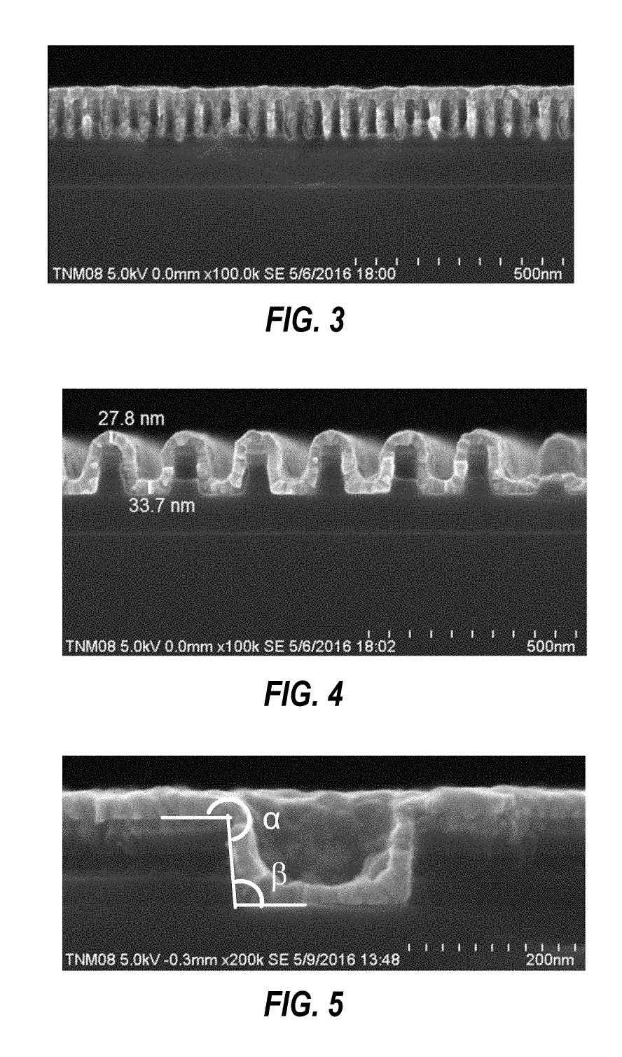

FIGS. 2A and 2B shows cross-sectional SEM images of Ru metal filling of fine recessed features in a substrate according to an embodiment of the invention. The recessed features in FIG. 2A had diameters (widths) ranging from about 10 nm (left) to about 40 nm (right) and depths of about 195 nm. The recessed features in FIG. 2B had diameters ranging from about 20 nm to about 35 nm and depths of about 95 nm. A lower magnification of the SEM in FIG. 2B is shown in FIG. 3. Prior to Ru metal deposition, a 1 nm thick TaN nucleation layer was deposited in the recessed features using ALD with alternating exposures of TBTEMT and NH₃ at a substrate temperature of about 350° C. A Ru metal layer was deposited at a rate of about 1.0-1.5 nm/min on the TaN nucleation layer by CVD a substrate temperature of less than 200° C. using Ru₃(CO)₁₂ and CO carrier gas. The processing conditions further included a gas pressure in the process chamber between about 0.05 and about 5.0 mTorr. The gas pressure was not controlled using an APC system but rather the process chamber was evacuated at a maximum pumping rate (open throttle).

FIGS. 2A and 2B show that all the recessed features were completely filled with Ru metal, with no voids visible in the recessed features. The inventors have discovered that processing conditions that achieve void-less Ru metal filling using Ru₃(CO)₁₂ and CO carrier gas include a substrate temperatures between about 100° C. and less than 200° C., between about 100° C. and about 180° C., between about 130° C. and about 160° C., or between about 130° C. and about 140° C. The gas pressure in the process chamber can, for example, be less than about 15 mTorr, less than about 10 mTorr, less than about 5 mTorr, or between about 0.05 mTorr and about 5 mTorr. The substrates in FIGS. 2A and 2B may be further processed, for example by performing a planarization process (e.g., chemical mechanical polishing (CMP)) that removes excess Ru metal from above the recessed features.

The void-less Ru metal filling of the recessed features in FIGS. 2A and 2B is thought to be enabled by the high surface tension of the deposited Ru metal that causes inward attraction of Ru metal atoms at a curved boundary. This results in increased local Ru metal deposition at the bottom of a recessed feature where the curving angle is increasing (corner angle decreasing) during the bottom-up Ru metal deposition. The inventors have identified key process parameters for achieving void-less bottom-up Ru metal filling, including low substrate temperature, low process chamber pressure, and high Ru metal deposition rate. Void-less bottom-up metal filling is expected to be achievable for other metals than Ru metal by using this approach and the same or similar processing conditions that have been identified for Ru metal filling. According to one embodiment, the metal may be selected from the group consisting of Ru, Rh, Os, Pd, Ir, Pt, Ni, Co, W, and combinations thereof. According to another embodiment, the metal may be a noble metal that is selected from the group consisting of Ru, Rh, Pd, Os, Ir, Pt, and combinations thereof.

FIG. 4 shows cross-sectional SEM images of Ru metal deposition in wide recessed features in a substrate according to an embodiment of the invention. The recessed features had a width of about 130 nm and a depth of about 120 nm. FIG. 4 illustrates the increased local Ru metal deposition near the bottom of the recessed features compared to near the top of the recessed features.

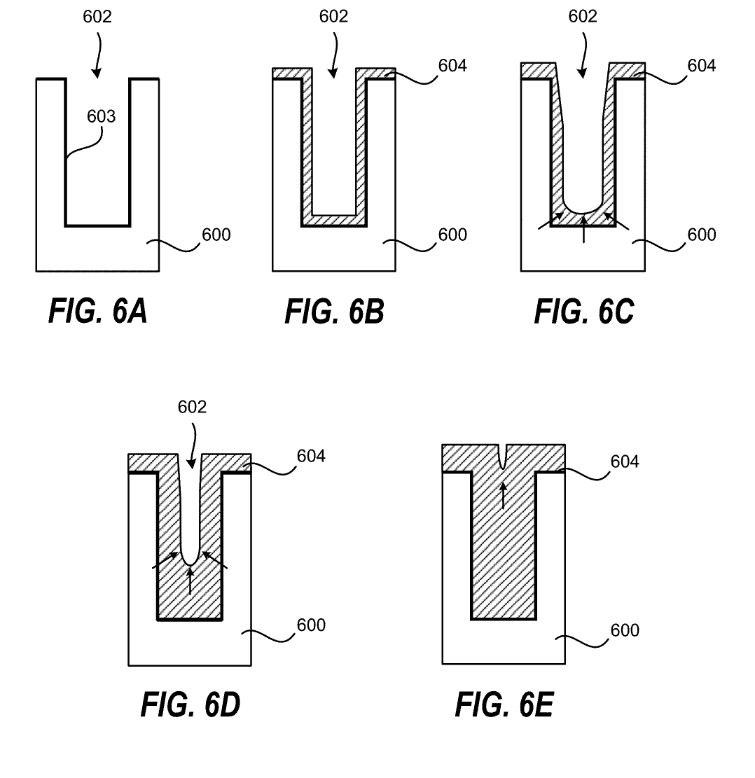

This is further demonstrated in FIG. 5 where a thickness of the deposited Ru metal layer is greater near a corner at the bottom of the recessed feature (having a corner angle β of about 90 degrees) than at the top of the recessed feature corner (having an angle α of about 270 degrees). Additional Ru metal deposition further promotes bottom-up void-less filling since the curving angle of the Ru metal layer in the recessed feature is further increased. This is further demonstrated in FIGS. 6A-6E.

FIGS. 6A-6E show schematic cross-sectional views of bottom-up metal filling mechanism of recessed features according to an embodiment of the invention. FIG. 6A schematically shows a recessed feature 602 in a substrate 600 and an optional nucleation layer 603 in the recessed feature 602. As shown in FIG. 6B, initial metal deposition forms a conformal metal layer 604 inside the recessed feature 602 and outside of the recessed feature 602. Further metal deposition using low substrate temperature, low process chamber pressure, and high metal deposition rate promotes bottom-up metal filling as shown in FIGS. 6C and 6D, where the curving angle of the metal filling indicated by the arrows in recessed feature 602 is steadily increasing (corner angle decreasing). FIG. 6E shows complete metal filling of the recessed feature 602.

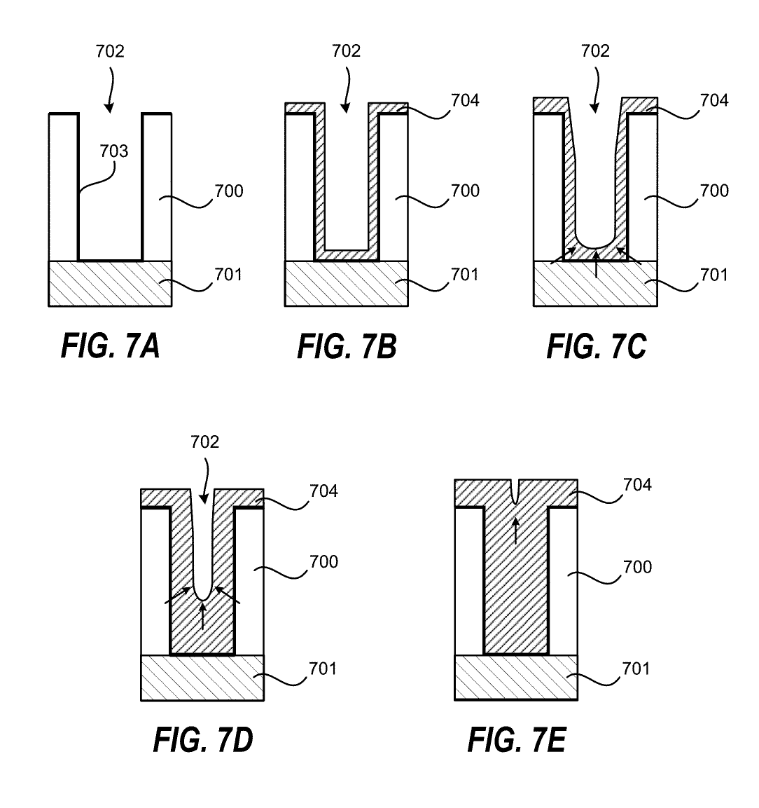

FIGS. 7A-7E show schematic cross-sectional views of bottom-up metal filling mechanism of recessed features according to an embodiment of the invention. FIG. 7A schematically shows a recessed feature 702 in a substrate 700 overlying a metal-containing layer 701. The recessed feature 702 may be a via (hole) that vertically connects metal-containing interconnect lines (trenches), the metal-containing layer 701 being a lower level interconnect line underneath the recessed feature 702. According an embodiment of the invention, the metal-containing layer 701 may be selected from the group consisting of W, Co, Ti, TiN, NiSiₓ, and combinations thereof. As shown in FIG. 7B, initial metal deposition on an optional nucleation layer 703 forms a conformal metal layer 704 inside the recessed feature 702 and outside of the recessed feature 702. Further metal deposition using low substrate temperature, low process chamber pressure, and high metal deposition rate promotes bottom-up void-less filling as shown in FIGS. 7C and 7D, where the curving angle of the metal filling indicated by the arrows in recessed feature 702 is steadily increasing (corner angle decreasing). FIG. 7E shows complete metal filling of the recessed feature 702.

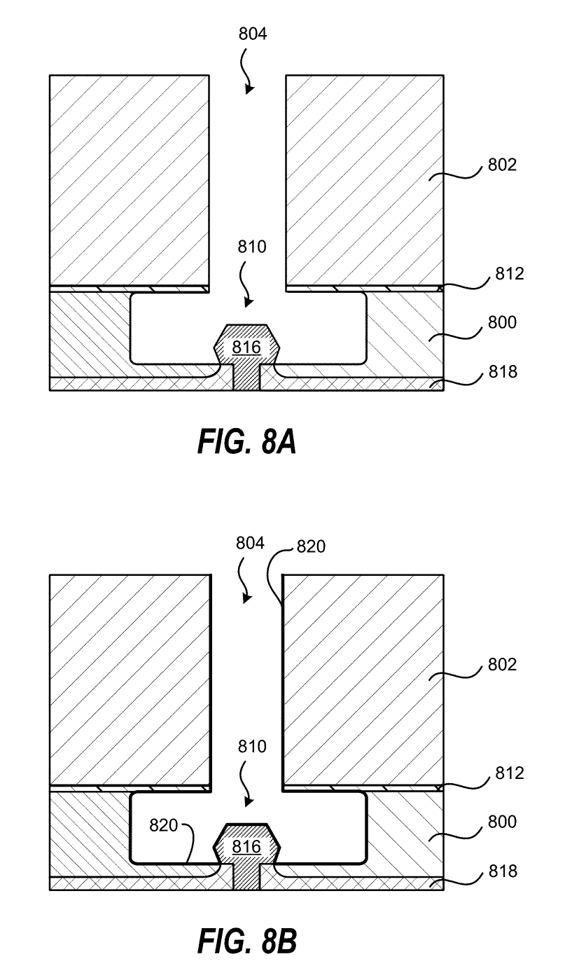

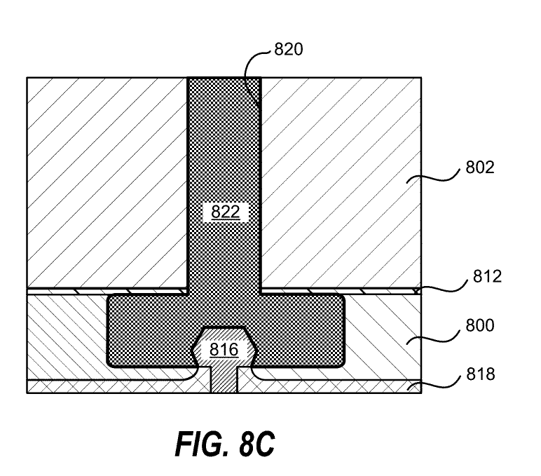

FIGS. 8A-8C show schematic cross-sectional views of bottom-up metal filling of a recessed feature according to an embodiment of the invention. In FIG. 8A, the substrate contains a raised contact 816 in a cavity 810 in a first dielectric film 800, and a second dielectric film 802 on the first dielectric film 800, where the second dielectric film 802 has a recessed feature 804 above the raised contact 816. The substrate further includes an etch stop layer 812 on the first dielectric film 800, and a dielectric film 818 underneath the first dielectric film 800. The etch stop layer 812 may be used to terminate the etching during the formation of the recessed feature 804. The etch stop layer 812 may, for example, include, a high-k material, silicon nitride, silicon oxide, carbon, or silicon. In some examples, the first dielectric film 800 may contain Sift, SiON, SiN, a high-k material, a low-k material, or an ultra-low-k material. In some examples, the second dielectric film 802 may contain Sift, SiON, SiN, a high-k material, a low-k material, or an ultra-low-k material. In one example, the raised contact may include SiGe, SiC, or SiP.

FIG. 8B shows the substrate following conformal deposition of a metal-containing contact layer 820. The metal-containing contact layer 820 is electrically conductive and can, for example, be selected from the group consisting of Ti, TiSi, NiSi, NiPtSi, Co, CoSi, and combinations thereof. Thereafter, as shown in FIG. 8C, the recessed feature 804 and the cavity 810 may be filled with metal 822.

According to another embodiment, a nucleation layer (not shown) may be conformally deposited on the metal-containing contact layer 820 in the recessed feature 804 and the cavity 810 and, thereafter, the recessed feature 804 and the cavity 810 may be filled with metal. According to one embodiment, the nucleation layer may be selected from the group consisting of Mn, MnN, Mo, MoN, Ta, TaN, W, WN, Ti, and TiN.

According to another embodiment, the metal-containing contact layer 820 may be isotropically etched to at least substantially remove the metal-containing contact layer 820 from surfaces in the recessed feature 804 and the cavity 810, while leaving at least a portion of the metal-containing layer on the raised contact 816. Thereafter, the recessed feature 804 and the cavity 810 may be filled with metal. Optionally, a conformal nucleation layer may be deposited prior to the metal filling.

According to one embodiment, the metal filled recessed features may subsequently be heat-treated to increase the grain sizes of the metal fill and further lower the electrical resistance of the metal fill. According to one embodiment, the metal may be deposited at a first substrate temperature and the heat-treating may be performed at a second substrate temperature that is greater than the first substrate temperature. In one example, Ru metal deposition may be performed at a first substrate temperature between about 100° C. and less than about 200° C. and the heat-treating may be performed at a second substrate temperature between 200° C. and 600° C., between 300° C. and 400° C., between 500° C. and 600° C., between 400° C. and 450° C., or between 450° C. and 500° C. Further, the heat-treating may be performed at below atmospheric pressure in the presence of Ar gas, H₂ gas, or both Ar gas and H₂ gas. In one example, the heat-treating may be performed at below atmospheric pressure in the presence of forming gas. Forming gas is a mixture of H₂ and N₂. In another example, the heat-treating may be formed under high-vacuum conditions without flowing a gas into a process chamber used for the heat-treating.

According to one embodiment, the heat-treating may be performed in the presence of a gaseous plasma. This allows for lowering the heat-treating temperature compared to when a gaseous plasma is not employed. This allows the use of heat-treating temperatures that are compatible with low-k materials with 2.5≦k<3.9 and ultra-low-k materials with k<2.5. In one example, the gaseous plasma can include Ar gas. The plasma conditions may be selected to include low-energy Ar ions.

The recessed feature can, for example, include a trench or a via. The feature diameter can be less than 100 nm, less than 50 nm, less than 30 nm, less than 20 nm, less than 10 nm, or less than 5 nm. The recessed feature diameter can be between 50 nm and about 100 nm, between 20 nm and 30 nm, between 10 nm and 20 nm, between 5 nm and 10 nm, or between 3 nm and 5 nm. A depth of the recessed feature can, for example be greater 20 nm, greater than 50 nm, greater than 100 nm, or greater than 200 nm. The features can, for example, have an aspect ratio (AR, depth:width) between 2:1 and 20:1, between 2:1 and 10:1, or between 2:1 and 5:1. In one example, the substrate (e.g., Si) includes a dielectric layer and the feature is formed in the dielectric layer.

According to some embodiments, a nucleation layer may be deposited in the features by ALD or CVD prior to the metal fill. According to one embodiment, a nucleation layer may be omitted. The optional nucleation can, for example, include a nitride material. According to one embodiment, the nucleation layer may be selected from the group consisting of Mn, MN, Mo, MoN, Ta, TaN, W, WN, Ti, and TiN. A role of the nucleation layer is to provide a good nucleation surface and an adhesion surface for metal in the recessed feature to ensure conformal deposition of the metal layer with a short incubation time. Unlike when using a Cu metal fill, a good barrier layer is not required between the dielectric material and a Ru metal in the features. Therefore, in the case of a Ru metal fill, the optional nucleation layer can be very thin and may be non-continuous or incomplete with gaps that expose the dielectric material in the features. This allows for increasing the amount of Ru metal in a feature fill compared to a Cu metal feature fill. In some examples, a thickness of the nucleation layer can be 20 Å or less, 15 Å or less, 10 Å or less, or 5 Å or less.

Methods for void-less filling of recessed features such as vias and trenches with a low resistivity metal (e.g., Ru metal) for microelectronic devices have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of metal filling recessed features on a substrate, the method comprising:
providing a substrate containing recessed features therein; and
filling the recessed features with a metal, wherein the metal is deposited in the recessed features by gas phase deposition at substrate temperature and a gas pressure that promotes bottom-up void-less filling.

2. The method of claim 1, wherein the metal is selected from the group consisting of Ru, Rh, Os, Pd, Ir, Pt, Ni, Co, W and combination thereof.

3. The method of claim 1, wherein the metal is a noble metal that is selected from the group consisting of Ru, Rh, Os, Pd, Ir, Pt, and combination thereof.

4. The method of claim 1, further comprising, prior to the filling, forming a nucleation layer in the recessed features.

5. The method of claim 4, wherein the nucleation layer is selected from the group consisting of Mn, MnN, Mo, MoN, Ta, TaN, W, WN, Ti, and TiN.

6. The method of claim 1, wherein the substrate temperature is between about 100° C. and less than 200° C. and the gas pressure is less than about 15 mTorr.

7. A method of metal filling recessed features on a substrate, the method comprising:
providing a substrate containing recessed features therein; and
filling the recessed features with Ru metal, wherein the Ru metal is deposited in the recessed features by gas phase deposition at substrate temperature and a gas pressure that promotes bottom-up void-less filling.

8. The method of claim 7, wherein the Ru metal is deposited by atomic layer deposition (ALD) or chemical vapor deposition (CVD).

9. The method of claim 7, wherein the Ru is deposited by chemical vapor deposition (CVD) using Ru₃(CO)₁₂ and CO carrier gas.

10. The method of claim 9, wherein the substrate temperature is between about 100° C. and less than 200° C.

11. The method of claim 9, wherein the substrate temperature is between about 130° C. and about 160° C.

12. The method of claim 9, wherein the gas pressure is less than about 15 mTorr.

13. The method of claim 9, wherein the gas pressure is between about 0.05 mTorr and about 5 mTorr.

14. The method of claim 9, wherein the substrate temperature is between about 100° C. and less than 200° C. and the gas pressure is less than about 15 mTorr.

15. The method of claim 7, wherein a deposition rate of the Ru metal is between about 1.0 nm/min and about 1.5 nm/min.

16. The method of claim 7, further comprising, prior to the filling, forming a nucleation layer in the plurality of recessed features.

17. The method of claim 16, wherein the nucleation layer is selected from the group consisting of Mn, MnN, Mo, MoN, Ta, TaN, W, WN, Ti, and TiN.

18. The method of claim 7, further comprising
heat-treating the substrate to increase the grain sizes of the Ru metal, wherein the Ru metal is deposited at a first substrate temperature and the heat-treating is performed at a second substrate temperature that is greater than the first substrate temperature.

19. The method of claim 18, wherein the second substrate temperature is between about 200° C. and about 600° C.

20. A method of metal filling recessed features on a substrate, the method comprising:
providing a substrate containing recessed features therein;
filling the recessed features with Ru metal, wherein the Ru metal is deposited in the recessed features by chemical vapor deposition (CVD) using Ru₃(CO)₁₂ and CO carrier gas at substrate temperature between about 130° C. and about 160° C. and a gas pressure between about 0.05 mTorr and about 5 mT
